(19) United States
(12) Patent Application Publication
(10) Pub. No.: US 2017/0127567 A1
(43) Pub. Date: May 4, 2017

(54) ELECTRONIC DEVICE EQUIPPED WITH A HEAT SINK

(71) Applicant: STMicroelectronics (Grenoble 2) SAS, Grenoble (FR)

(72) Inventors: Benoit Besancon, Villard Bonnot (FR); Agnes Baffert, Moirans (FR); Karine Saxod, Les Marches (FR)

(73) Assignee: STMicroelectronics (Grenoble 2) SAS, Grenoble (FR)

(21) Appl. No.: 15/131,652

(22) Filed: Apr. 18, 2016

(30) Foreign Application Priority Data
Oct. 28, 2015 (FR) 1560313

(51) Int. Cl. H05K 7/20; H05K 1/02; H05K 1/18

(52) U.S. Cl. CPC H05K 7/20509; H05K 1/181; H05K 1/0203; H05K 2201/10734; H05K 2201/066

(57) ABSTRACT

An electronic device includes a support plate with an integrated circuit chip fixed onto the support plate. A heat sink is mounted to the support plate. An electrical connection wire is provided with one end electrically connected to the heat sink and another end electrically connected to an electrical contact provided on the support plate.

### PRIORITY CLAIM

This application claims priority from French Application for Patent No. 1560313 filed Oct. 28, 2015, the disclosure of which is incorporated by reference.

### TECHNICAL FIELD

The present invention relates to the field of electronic devices.

### BACKGROUND

Electronic devices may comprise an integrated circuit chip mounted in a package, for example of the BGA type, the chip being fixed onto a front side of a support plate. A heat sink, generally made of metal, may take the form of a bowl and comprise a frontal plate extending above the chip. A peripheral base is connected to this frontal plate and fixed above the front side of the support plate. An encapsulation block is provided above the front side of the support plate, in which the chip and the heat sink are embedded in such a way that the front side of the frontal plate of this sink is uncovered.

In a routine manner, the base of the heat sink is fixed onto the support plate by means of an electrically conductive adhesive extending over an electrical contact of the front side of the support plate, so as to connect the sink to an electrical earth.

During the production of the encapsulation block by injection molding in a cavity of a mold, a face of this cavity firmly supports the frontal plate of the heat sink. This support causes a deformation of the sink such that the conductive adhesive detaches from the electrical contact, to the extent that it is not possible to be certain that the heat sink remains properly connected to the electrical ground.

There is a need in the art to remedy this drawback.

### SUMMARY

An electronic device is proposed which comprises a support plate, an integrated circuit chip fixed onto the support plate, a heat sink and an electrical connection wire having one end fixed onto the heat sink and another end fixed onto an electrical contact provided on the support plate.

In this way, the electrical connection of the heat sink is independent of the fixation of the sink onto the support plate.

The electronic device can comprise an encapsulation block above the support plate, in which the chip and the heat sink are encapsulated, the electrical connection wire being embedded in this encapsulation block.

The heat sink can comprise a frontal plate extending above the chip and a peripheral base connected to this frontal plate and fixed above the support plate.

The frontal plate of the heat sink can be at least partly uncovered.

The support plate can be equipped with an electrical connection network, the integrated circuit chip can be fixed onto a front side of the support plate and the heat sink can comprise a frontal plate extending above the chip and a peripheral base connected to this frontal plate and fixed above the front side of the support plate.

Provision may be made for an encapsulation block above the front side of the support plate, in which block the chip and the heat sink are encapsulated in such a way that the front side of the frontal plate of the sink is at least partly uncovered, the electrical connection wire being embedded in said encapsulation block and having one end fixed onto said base of the heat sink and another end fixed onto an electrical contact of said network, provided on the front side of the support plate.

The encapsulation block can have one front side located in the same plane as the front side of the frontal plate of the heat sink.

### BRIEF DESCRIPTION OF THE DRAWINGS

The heat sink can be made of metal. An electronic device and a manufacturing method will now be described as exemplary embodiments, illustrated by the drawing in which:

FIG. 1 shows a top view of an electronic device, without encapsulation block; and

FIG. 2 shows a section along II-II of FIG. 1, with its encapsulation block.

### DETAILED DESCRIPTION

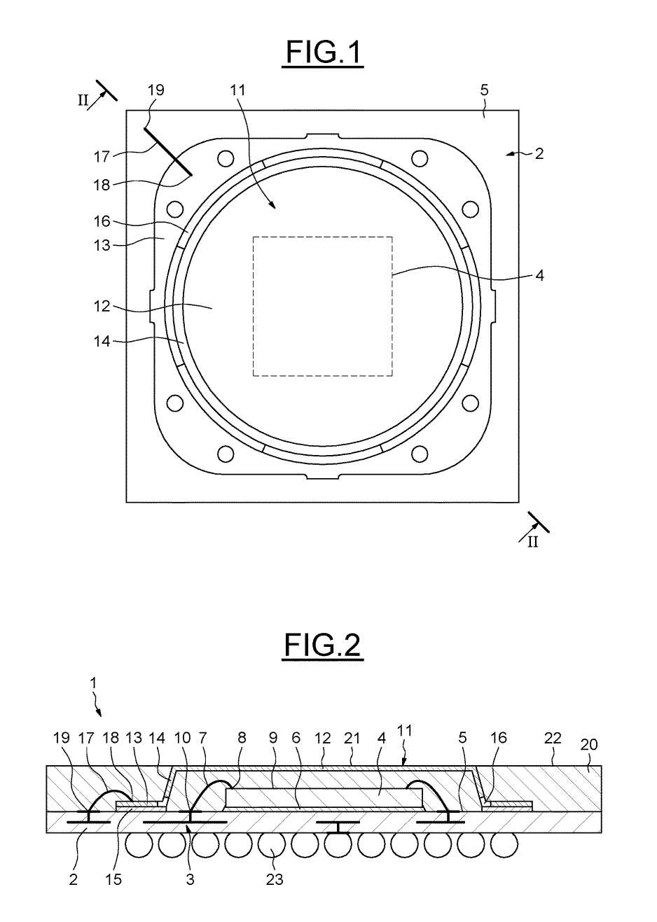

An electronic device 1 shown in FIGS. 1 and 2 comprises a support plate 2 incorporating an electrical connection network 3 and an integrated circuit chip 4 fixed onto a front side 5 of the support plate, substantially in its middle, by means of a layer of adhesive 6.

The chip 4 is electrically connected to the network 3 by means of a plurality of electrical connection wires 7, one end of which is soldered onto electrical contacts 8 of a front side 9 of the chip 4 and another end is soldered onto front electrical contacts 10 of the network 3, which contacts are provided on the front side 5 of the support plate 2, away from the periphery of the chip 4.

According to a variant embodiment, the chip 4 could be mounted on the support plate 2 by means of electrical connection elements such as balls. In this case, the electrical wires 7 could be omitted.

The electrical device 1 comprises a heat sink 11, made of metal, which comprises a frontal plate 12 which extends above and away from the front side 9 of the chip 4 and the electric wires 7, a peripheral flange 13 which extends above the front side 5 of the support plate 2, away from and on the outside of the electrical contacts 10 and a sloping annular connecting portion 14, in such a way that the heat sink 11 takes the form of a bowl on the inside of which the chip 4 and the electrical wires 7 are located.

The peripheral flange 13 is fixed onto the face of the front side 5 of the support plate 2 by means of a layer of adhesive 15.

The heat sink 11 has access openings 16 provided peripherally in the connection area between the peripheral flange 13 and the annular connecting portion 14.

The electronic device 1 also comprises an electrical connection wire 17, an end of which is soldered onto the flange 13 at a point 18 and the other end of which is soldered onto a front electrical contact 19 of the network 3, provided on the front side 5 of the support plate 2, away from the periphery of the flange 13, with a view to connecting the heat sink 11 to an electrical ground. Other electrical wires 16 could be provided.

The electronic device 1 furthermore comprises an encapsulation block 20 formed above the front side 5 of the support plate 2, in which block the chip 4, the electrical wires 7, the heat sink and the electrical wire 17 are encapsulated, in such a way that the front side 21 of the frontal plate 12 of the heat sink 11 is uncovered.

The encapsulation block 20 fills the interior space of the heat sink 11, thereby embedding the chip 4 and the electrical wires 7, in such a way that the encapsulation block 20 extends into the space between the front side 9 of the chip 4 and around the chip 4 between the periphery of the chip and the annular connecting portion 14 on the corresponding area of the front side 5 of the support plate 2.

The encapsulation block 20 also extends around the annular portion 14 of the heat sink 11, above the flange 13 of the heat sink 11 and above the corresponding area of the front side 5 of the support plate, up to the peripheral edge of the support plate 2, so that the front side 21 of the frontal plate 12 of the heat sink 11 is not covered. The encapsulation block 20 has a front side 22 which extends in the same plane as the front side 21 of the frontal plate 12 of the heat sink 11, this plane being parallel to the support plate 2.

The result of the preceding is that the heat sink 11 is connected to the electrical connection network 3 by means of the electrical wire 17, independently of the fixation of the heat sink 11 onto the support plate 2 by means of the layer of adhesive 15.

The electronic device 1 can be manufactured in the following way.

The chip 4 is fixed onto the support plate 2.

The electrical wires 7 are put in place.

The heat sink 11 is fixed by virtue of the layer of adhesive 15.

The electrical wire 17 is put in place.

The encapsulation block 20 is produced in an injection mold, the internal cavity of the mold having a flat surface coming into contact with the front side 21 of the frontal plate 12 of the heat sink 11. Advantageously, the periphery of this front side 21 of the heat sink 11 can have an annular part slightly protruding forwards in contact with said surface of the cavity of the mold.

By virtue of the access openings 16 passing through the heat sink 11, the injected material penetrates the interior of the heat sink 11 in order to fill the free space between the heat sink and the chip 4.

After this, external electrical connection elements 23, such as balls, can be put in place on rear electrical contacts of the electrical connection network 3, which contacts are provided on the rear face of the support plate 2.

Electronic devices 1 can be collectively manufactured on a common support wafer, followed by singulation by sawing, as is known in the field of microelectronics.

1. An electronic device, comprising:
a support plate,
an integrated circuit chip fixed onto the support plate,
a heat sink made of a metal material wherein a bottom surface of said metal material at a peripheral flange of the heat sink is fixed onto a top surface of the support plate; and
an electrical connection wire having one end fixed onto a top surface of the metal material at the peripheral flange of the heat sink and another end fixed onto an electrical contact provided on the support plate.

2. The device according to claim 1, further comprising an encapsulation block above the support plate that encapsulates the integrated circuit chip and the heat sink, and wherein the electrical connection wire is embedded in the encapsulation block.

3. The device according to claim 2, wherein the heat sink comprises a frontal plate extending above the integrated circuit chip and wherein said peripheral flange is connected to this frontal plate.

4. (canceled)

5. The device according to claim 3, wherein the frontal plate of the heat sink is not covered by said encapsulation block.

6. The device according to claim 5, wherein a top surface of the encapsulation block is coplanar with a top surface of the frontal plate.

7. The device according to claim 1, wherein the support plate includes an electrical connection network, wherein the integrated circuit chip is fixed onto a front side of the support plate, wherein the heat sink comprises a frontal plate extending above the integrated circuit chip and a peripheral flange connected to the frontal plate and fixed to the front side of the support plate.

8. The device according to claim 7, further comprising an encapsulation block above the front side of the support plate that encapsulates the integrated circuit chip and the heat sink in such a way that the front side of the frontal plate is at least partly uncovered, and wherein the electrical connection wire is embedded in said encapsulation block.

9. The device according to claim 8, wherein one end of the electrical connection wire is fixed onto said peripheral flange of the heat sink and another end of the electrical connection wire is fixed onto an electrical contact of said electrical connection network.

10. The device according to claim 9, wherein the encapsulation block has one front side located in a same plane as the front side of the frontal plate of the heat sink.

11. (canceled)

12. The device according to claim 3, wherein the peripheral flange is connected to the frontal plate by an annular connecting portion, said heat sink further including access openings provided at a connection of the peripheral flange to the annular connecting portion.
